(19) United States
(12) Patent Application Publication
(10) Pub. No.: US 2025/0203757 A1
(43) Pub. Date: Jun. 19, 2025

(54) AIRTIGHT OPTICAL MODULE

(71) Applicant: Innolight Technology (ChengDu) LTD., Chengdu, Sichuan (CN)

(72) Inventors: Yin Wei, Chengdu, Sichuan (CN); Huan Jiang, Chengdu, Sichuan (CN); Hai-feng HE, Chengdu, Sichuan (CN); Peng Xiao, Chengdu, Sichuan (CN); Gang Chen, Chengdu, Sichuan (CN); Qing Huang, Chengdu, Sichuan (CN)

(21) Appl. No.: 18/707,634

(22) PCT Filed: Nov. 10, 2022
(86) PCT No.: PCT/CN2022/131065

§ 371 Date: Nov. 4, 2024

(30) Foreign Application Priority Data
Nov. 11, 2021 (CN) 202111332892.1

(51) Int. Cl. H05K 1/02

(52) U.S. Cl. CPC H05K 1/0237; H05K 1/0203; H05K 1/0274; H05K 2201/10121

(57) ABSTRACT

An airtight optical module, comprising: a box-shaped tube shell (10), a rear end wall (113) of which is provided with a channel groove (1130); a connector (30), which is embedded in the channel groove (1130), and has an upper layer surface (301) provided with a direct-current signal line (3D), and a lower layer surface (303) provided with a high-frequency signal line (3G), wherein the upper layer surface (301) is open upwards and comprises a first area (301a) located in front of the rear end wall (113) and a second area (301b) located behind the rear end wall (113), and the lower layer surface (303) comprises a third area (303a) which is located in front of the rear end wall (113) and is open upwards, and a fourth area (303b) which is located behind the rear end wall (113) and is open downwards; a chip carrier assembly (40), which is arranged in the tube shell (10), and comprises an optical chip (41) and a carrier (43), wherein the chip carrier assembly (40) is electrically connected to the direct-current signal line (3D) of the first area (301a) and the high-frequency signal line (3G) of the third area (303a); and a circuit board (20), the lower surface (23) of which is provided with a high-frequency signal line (3G) and is connected to a high-frequency signal line (3G) of the fourth area (303b) by means of a gold wire (53), and the upper surface (21) of which is provided with a direct-current signal line (3D) and is connected to a direct-current signal line (3D) of the second area (301b) by means of a gold wire (51). In this way, a high-frequency signal interconnection gold wire between the connector (30) and the circuit board (20) is short, thereby optimizing the high-frequency performance.

### CROSS-REFERENCE TO RELATED PATENT APPLICATION

This is the U.S. national phase application of International Application PCT/CN2022/131065, filed on Nov. 10, 2022, which international application was published on May 19, 2023, as International Publication No. WO 2023/083244. The international application claims priority to China Patent Application No. 202111332892.1, filed on Nov. 11, 2021, the contents of which are incorporated herein by reference in their entireties.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an optical communication element manufacturing technological field, and more particularly to an airtight optical module.

### BACKGROUND OF THE DISCLOSURE

Currently, driven by the demand for the 5G wireless fronthaul and ultra-large-scale broadband data centers in the fifth-generation communication network, speed requirements of the optical transceiver module that is a core component is gradually increased.

The commonly used packaging forms of an airtight optical module include a BOX packaging structure, in which chip-on-ceramic (COC) assemblies (including optical chips and ceramic carriers with optical chips attached thereon), optical devices, etc. are assembled into a closed ceramic shell, and flexible circuit boards designed with direct-current signal lines and high-frequency signal lines are provided. The external PCBA of the ceramic shell realizes the direct-current signal connection and high-frequency signal connection with the optical chips through the flexible circuit board and gold wires. Comparing to such as a TO packaging structure, especially for multi-channel high speed optical modules, the BOX packaging structure has the advantages such as product miniaturization and easy heat dissipation.

However, the existing BOX packaging technology still has the following problems: in one aspect, multiple impedance discontinuities being present in the high-speed link between the optical chip and the external PCBA makes it difficult to further optimize the high-frequency performance in higher-speed applications; and in another aspect, the length of the gold wires being large makes it difficult to be shortened to optimize the high-frequency performance.

### SUMMARY OF THE DISCLOSURE

In response to the above-referenced technical inadequacies, the present disclosure provides an airtight optical module.

In order to solve the above-mentioned problems, one of the embodiments provides an airtight optical module, including:
a box-shaped tube shell, a rear end wall of which is provided with a channel groove;
a connector being embedded in the channel groove and having an upper layer surface and a lower layer surface, in which the upper layer surface is open upwards and includes a first area located in front of the rear end wall and a second area located behind the rear end wall, and the upper layer surface includes a direct-current signal line arranged thereon that extends from the first area to the second area; in which the lower layer surface includes a third area located in front of the rear end wall and is open upwards and a fourth area located behind the rear end wall and is open downwards, and the lower layer surface includes a high-frequency signal line arranged thereon that extends from the third area to the fourth area;
a chip carrier assembly disposed in the tube shell and including an optical chip and a carrier that carries the optical chip, in which the chip carrier assembly is electrically connected to the direct-current signal line of the first area and the high-frequency signal line of the third area; and
a circuit board, in which a lower surface thereof has a high-frequency signal line arranged thereon and connected to the high-frequency signal line of the fourth area by means of a gold wire, and an upper surface of the circuit board has a direct-current signal line disposed thereon and connected to the direct-current signal line of the second area by means of a gold wire.

Preferably, the connector includes:
a first pad; and
a second pad, in which a front end thereof is step-shaped and stacked on and fixed above the first pad, and a rear end thereof is suspended, the first area and the second area are defined on an upper surface of the second pad; in which the fourth area is defined on a lower surface thereof;
a front part of the upper surface of the first pad is exposed by the second pad to form the third area.

Preferably, the carrier is provided in front of the first pad and electrically connected to the high-frequency signal line on the third area and the direct-current signal line on the first area, respectively, by mean of gold wires.

Preferably, the carrier is disposed separately from the connector.

Preferably, the connector is hermetically connected to the rear end wall to close the channel groove.

Preferably, the connector is connected to the rear end wall by means of soldering.

Preferably, the connector further includes a protective wall, the protective wall protrudes upwardly from the upper surface of the second pad to divide the first area and the second area, and an upper surface of the protective wall is hermetically connected to an upper groove wall of the channel groove.

Preferably, the first pad, the second pad, and the protective wall are provided as a ceramic plate and are integrally fixed by means of one of laminating, heat-cutting, and sintering.

Preferably, the upper surface of the circuit board is higher than the fourth area, and the lower surface of the circuit board is lower than the second area.

Preferably, the lower surface of the circuit board is flush with the fourth area.

Preferably, the tube shell has a support pad that extends rearward from the rear end wall, and the circuit board is fixedly assembled with the support pad.

Preferably, the support pad is located below the circuit board and has a clearance groove that is a top-down perforation; in which a projection range of the clearance groove in a top-down direction covers gold wire solder joints on the high-frequency signal line in the fourth area and gold wire solder joints on the high-frequency signal line on the lower surface of the circuit board;
alternatively, the support pad is located above the circuit board and has a clearance groove that is a top-down perforation; in which a projection range of the clearance groove in a top-down direction covers gold wire solder joints on the direct-current signal line of the second area and gold wire solder joints on the direct-current signal line on the upper surface of the circuit board.

Preferably, the tube shell includes a shell base and a cover plate, the shell base includes an upper opening and a bottom wall that is closed, and the cover plate seals the opening;
the carrier is thermally conductively mounted to the bottom wall through one or both of a heat sink and a cooler.

Preferably, a front end wall of the tube shell has an optical window formed thereon; and the airtight optical module further comprising:
an optical port assembly mounted at the optical window; and
one or more of a collimating lens, a wavelength division multiplexing-demultiplexing element, an isolator, a coupling lens, a modulator, and a filter arranged in the tube shell and disposed between the optical port assembly and the optical chip.

Preferably, the optical chip is one of a laser chip and a photodetector chip.

In order to solve the above-mentioned problems, one of the embodiments provides an airtight optical module, including:
a tube shell defining an accommodating cavity, and a rear end wall of which is provided with a channel groove;
a connector being embedded in the channel groove, in which the connector has a first pad with a high-frequency signal line arranged on an upper surface thereof, and a second pad with a direct-current signal line arranged on an upper surface thereof and a high-frequency signal line arranged on a lower surface thereof; in which a front end of the second pad is step-shaped and stacked on and fixed above the first pad, and extends into the accommodating cavity; in which a rear end of the second pad is arranged behind the rear end wall and is suspended;
a chip carrier assembly disposed in the accommodating cavity and including an optical chip and a carrier that carries the optical chip, in which the chip carrier assembly is electrically connected to the direct-current signal line on the upper surface of the second pad and the high-frequency signal line on the upper surface of the first pad; and
a circuit board disposed outside the accommodating cavity, in which a lower surface thereof has a high-frequency signal line arranged thereon and connected to the high-frequency signal line of the lower surface of the second pad by means of a gold wire, and an upper surface thereof has a direct-current signal line arranged thereon and connected to the direct-current signal line of the upper surface of the second pad by means of a gold wire.

Preferably, the tube shell has a support pad that extends rearward from the rear end wall, and the circuit board is fixedly assembled with the support pad.

Preferably, the support pad has a clearance groove for exposing a connection position of the connector and the circuit board.

Preferably, the circuit board is a rigid circuit board.

Comparing with the commonly used technologies, the technical effect of the present disclosure is as follows: by providing the connector, specifically placing the surface for the wiring of the high-frequency signal line on the connector and the surface for the wiring of the high-frequency signal line on the circuit board on the same side in the top-down direction (correspondingly, the surface for the wiring of the direct-current signal line on the connector and the surface for the wiring of the high-frequency signal line on the circuit board are located on the same side in the top-down direction); and the surfaces for the wiring of the direct-current signal line on the connector facing in opposite directions inside and outside of the tube shell, the high-frequency signal connection between the connector and the circuit board can be realized with a very short length of the gold wire and the number of impedance discontinuities in the high-speed link between the chip carrier assembly and the circuit board can be greatly reduced, which is conducive to the optimization of the high-frequency performance of the optical module.

### BRIEF DESCRIPTION OF THE DRAWINGS

FIG. 1a is a schematic perspective structural view of an optical module according to one embodiment of the present disclosure;

FIG. 1b is a cross-sectional view taken along line A-A of FIG. 1a, in which line A-A is co-linear with a center axis of an optical window;

FIG. 2a is a schematic perspective structural view of a tube shell according to one embodiment of the present disclosure;

FIG. 2b is a cross-sectional view of the tube shell of FIG. 2a, in which the cross-section is taken across the center axis of the optical window and is perpendicular to a left-right direction;

FIG. 3 is a schematic structural view of a connector according to one embodiment of the present disclosure;

FIG. 4 is a schematic structural view of a chip carrier assembly and a connector according to one embodiment of the present disclosure;

FIG. 5 is a partially enlarged view of an area B of FIG. 1b;

FIG. 6 is a schematic perspective structural view of an optical module taken in a viewing angle different from that of FIG. 1 according to one embodiment of the present disclosure; and

FIG. 7 is a partially schematic structural view of the optical module in which a circuit board and a cover plate are omitted according to one embodiment of the present disclosure.

### DETAILED DESCRIPTION OF THE EXEMPLARY EMBODIMENTS

The present application will be described in detail below with reference to specific embodiments as shown in the accompanying drawings. However, these embodiments do not limit the present application, and any structural, method, or functional changes made by those of ordinary skill in the art based on these embodiments are included in the protection scope of the present application.

Referring to FIG. 1a and FIG. 1b, one embodiment of the present disclosure provides an optical module 100, specifically a BOX package type airtight optical module, which includes a box-shaped metal tube shell 10, a circuit board 20 located outside the tube shell 10, a connector 30, and a chip carrier assembly 40 (also called as a COC assembly) located in the tube shell 10.

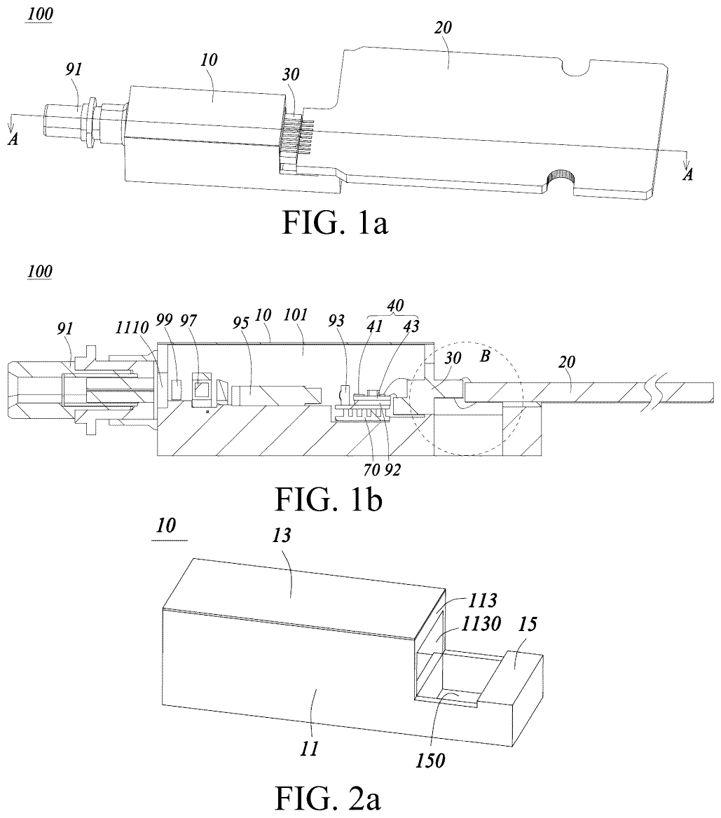

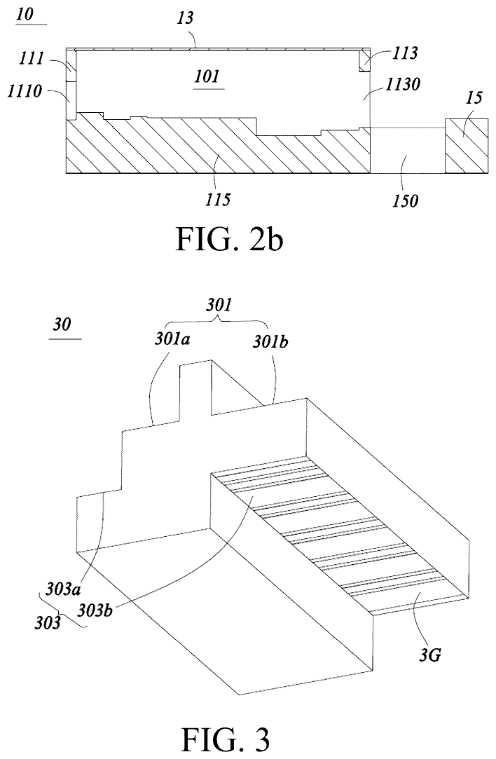

The tube shell 10 is used to hermetically package the chip carrier assembly 40 and a series of optical devices as described below. Specifically, referring to FIG. 2a, the tube shell 10 includes a shell base 11 and a cover plate 13. In which, referring to FIG. 2b, the shell base 11 includes a front end wall 111, a rear end wall 113, two left-right opposite side walls, a bottom wall 115, and an upper opening that is top-down opposite to the bottom wall 115; the cover plate 13 can be hermetically connected above the shell base 11 by parallel sealing welding or other processes to hermetically seal the upper opening of the shell base 11; the cover plate 13 and the shell base 11 jointly define an accommodating cavity 101, and the chip carrier assembly 40 is mounted in the accommodating cavity 101.

In this embodiment, a rear end wall 113 of the tube shell 10 has a channel groove 1130, and the connector 30 is embedded in the channel groove 1130. The chip carrier assembly 40 located in the tube shell 10 and the circuit board 20 located outside the tube shell 10 have signal connections therebetween that are realized through the connector 30.

Specifically, referring to FIG. 3, the connector 30 has an upper layer surface 301 and a lower layer surface 303; that is, the surface 301 is located relatively above the surface 303.

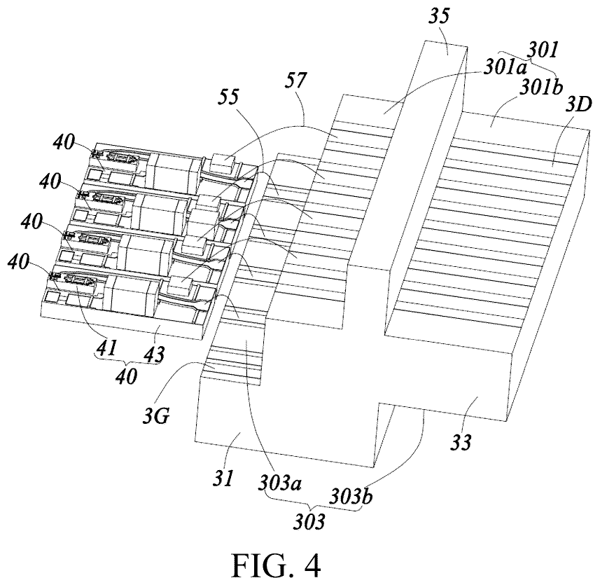

Furthermore: reference is simultaneously made to FIG. 3 and FIG. 4, and the upper layer surface 301 is open upwards and has a direct-current signal line 3D provided thereon. The upper layer surface 301 includes a first area 301a located in front of the rear end wall 113 and a second area 301b located behind the rear end wall 113; that is, the upper layer surface 301 is arranged across the rear end wall 113. A part of the front end of the upper layer surface 301 extends into the accommodating cavity 101 to form the first area 301a, and a part of the rear end of the same extends to the outside of the tube shell 10 to form the second area 301b. The direct-current signal line 3D extends from the first area 301a to the second area 301b.

The lower layer surface 303 has a high-frequency signal line 3G provided thereon, and includes a third area 303a located in front of the rear end wall 113 and open upwards and a fourth area 303b located behind the rear end wall 113 and open downwards; that is, the lower layer surface 303 is arranged across the rear end wall 113. A part of the front end of the lower layer surface 303 extends into the accommodating cavity 101 to form the third area 303a, and a part of the rear end of the same extends to the outside of the tube shell 10 to form the fourth area 303b. The high-frequency signal line 3G extends from the third area 303a to the fourth area 303b.

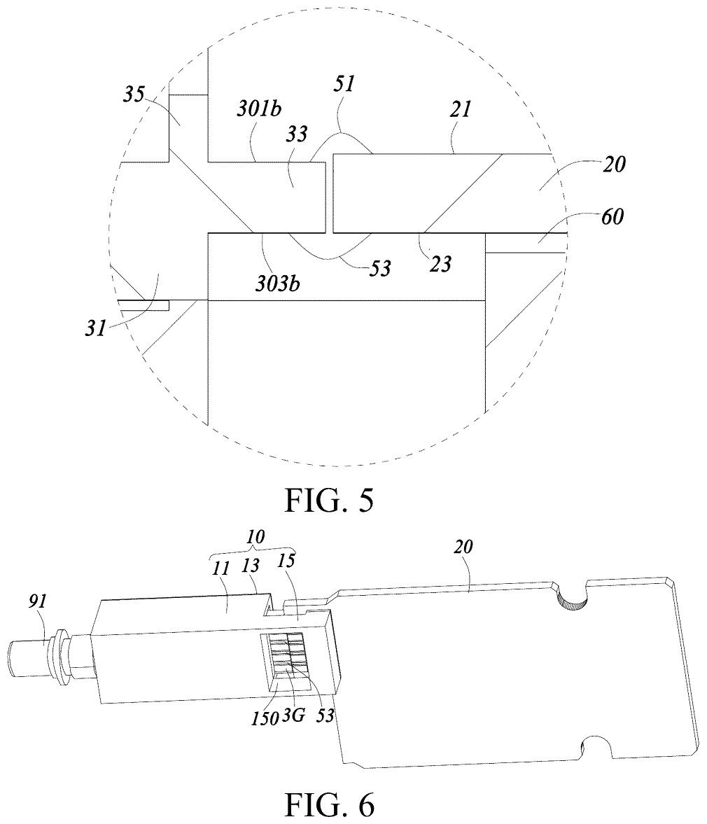

Furthermore, inside the tube shell 10, the chip carrier assembly 40 is electrically connected to the direct-current signal line 3D on the first area 301a and electrically connected to the high-frequency signal line 3G on the third area 303a; at the same time, referring to FIG. 5, outside the tube shell 10, a direct-current signal line is arranged on an upper surface 21 of the circuit board 20 and connected to the direct-current signal line 3D on the second area 301b by means of a gold wire 51; a high-frequency signal line is arranged on a lower surface 22 of the circuit board 20 and connected to the high-frequency signal line 3G on the fourth area 303b by means of a gold wire 53. In this way, the direct-current signal connection is realized between the chip carrier assembly 40 and the upper surface 21 of the circuit board 20 through the first area 301a, the second area 301b, and the gold wire 51, and the high-frequency signal connection is realized between the chip carrier assembly 40 and the lower surface 23 of the circuit board 20 through the third area 303a, the fourth area 303b, and the gold wire 53.

Accordingly, in the optical module 100 of the present embodiment, the connector 30 is provided, the surface 303 for the wiring of the high-frequency signal line 3G on the connector 30 and the surface 23 for the wiring of the high-frequency signal line on the circuit board 20 are specifically placed on the same side in a top-down direction (correspondingly, the surface 301 for the wiring of the direct-current signal line 3D on the connector 30 and the surface 21 for the wiring of the direct-current signal line on the circuit board 20 are located on the same side in the top-down direction), and the third area 303a inside the tube shell 10 and the fourth area 303b outside the tube shell 10 of the surface 303 face in opposite directions. Therefore, a very short gold wire 53 can be used to realize high-frequency signal connection between the connector 30 and the circuit board 20, and the number of impedance discontinuities in the high-speed link between the chip carrier assembly 40 and the circuit board 20 can be greatly reduced, which is conducive to the optimization of the high-frequency performance of the optical module 100. Naturally, in this embodiment, the two top-down opposite surfaces of the circuit board 20 (for example, the surface 23 and the surface 21) can both be connected to the connector 30 by using extremely short gold wires.

Regarding the connector 30, referring to FIG. 4, it may specifically include a first pad 31 and a second pad 33. In which, a front end of the second pad 33 is step-shaped and stacked on and fixed above the first pad 31. Correspondingly, the direct-current signal line 3D is arranged on an upper surface of the second pad 33, and the first area 301a and the second area 301b are formed on the upper surface; the high-frequency signal line 3G is arranged on an upper surface of the first pad 31, and a front part of the upper surface is exposed by the second pad 33 to form the third area 303a; the high-frequency signal line 3G is arranged on a lower surface of the second pad 33, a rear end of the second pad 33 is suspended, and a lower surface of the part of the suspended second pad 33 forms the fourth area 303b. Naturally, the specific configuration of the connector 30 is not limited thereto, and can also be implemented through other feasible modified configurations.

Furthermore, the first pad 31 and the second pad 33 are respectively provided as ceramic plates, and can be integrally fixed by means such as laminating, heat-cutting, and sintering.

Furthermore, referring to FIG. 4, the chip carrier assembly 40 is disposed in front of the first pad 31, electrically connected to the high-frequency signal line 3G on the third area 303a through a gold wire 55, and electrically connected to the direct-current signal line 3D on the first area 301a through a gold wire 57. In this way, in this embodiment, by arranging the first pad 31 and the second pad 33 into a step-shaped structure with the third area 303a relatively forward and the first area 301a relatively behind, a distance from the chip carrier assembly 40 to the third area 303a is smaller relative to a distance to the first area 301a. Therefore, the gold wire 57 for direct-current signal interconnection that does not have much requirement on length is relatively longer, and the gold wire 55 used in the high-frequency signal interconnection is ensured to be shorter in length, thereby further improving a high-frequency performance.

Specifically, the chip carrier assembly 40 specifically includes an optical chip 41 and a ceramic carrier 43 that carries the optical chip 41. In this embodiment, the carrier 43 is arranged in front of the first pad 31 and is separate from the first pad 31, and an upper surface thereof has a high-frequency signal line and a direct-current signal line provided thereon; the high-frequency signal line on the upper surface of the carrier 43 is electrically connected to the high-frequency signal line 3G on the third area 303a through the gold wire 55, and the direct-current signal line on the upper surface of the carrier 43 is electrically connected to the direct-current signal line 3D of the first area 301a through the gold wire 57, thereby realizing the high-frequency signal interconnection and the direct-current signal interconnection between the chip carrier assembly 40 and the connector 30; in addition, the optical chip 41 is fixedly mounted on the upper surface of the carrier 43, and is electrically connected with the high-frequency signal line and the direct-current signal line on the upper surface of the carrier 43. Naturally, in a modified implementation, the carrier 43 and the first pad 31 can also be integrally provided; for example, a front part of a ceramic plate is regarded as the carrier 43 and a rear part of the same is regarded as the first pad 31. Relatively, in the present embodiment, the carrier 43 and the first pad 31 are provided separately, which is more conducive to the assembly and heat dissipation of the optical module 100. Specifically, for example: the connector 30 and the chip carrier assembly 40 are independently fixed and mounted on the tube shell 10, respectively, which facilitates the optical axis alignment of the chip carrier assembly 40 and the optical device described below, and facilitates assembly; moreover, this facilitates the adjustment as required of a heat conduction manner between the chip carrier assembly 40 and the tube shell 10, and facilitates rapid heat dissipation of the optical chip 41.

Further, in addition to being used as a transmission medium for direct-current signals and high-frequency signals between the chip carrier assembly 40 and the circuit board 20, referring to FIG. 2a, the connector 30 is also hermetically connected to the rear end wall 113 of the tube shell 10 to close the channel groove 1130. Specifically, in one embodiment, the connector 30 and the rear end wall 113 can be hermetically connected by means of soldering, so as to ensure the sealing performance and the connection strength; naturally, the connection manner between the two is not limited thereto.

In detail, in one embodiment, referring to FIG. 5, the connector 30 further includes a protective wall 35. The protective wall 35 protrudes upward from the upper surface of the second pad 33 and divides the first area 301a and the second area 301b; an upper surface of the protective wall 35 is hermetically connected to an upper groove wall of the channel groove 1130 by soldering. In this way, on the upper surface of the second pad 33, the direct-current signal line 3D can cross the protective wall 35 and extend to the first area 301a and the second area 301b, such that the upper surface of the second pad 33 can be prevented from being directly soldered to the channel groove 1130 to cause a short circuit of the direct-current signal line 3D, thereby ensuring that the wiring of the direct-current signal line 3D is simple.

At the same time, regarding the connection between the connector 30 and the rear end wall 113, it is also configured as follows: between the lower surface of the first pad 31 and a lower groove wall of the channel groove 1130, between respective left surfaces of the first pad 31, the second pad 33, and the protective wall 35 and a left groove wall of the channel groove 1130, and between respective right surfaces of the first pad 31, the second pad 33, and the protective wall 35 and a right groove wall of channel groove 1130, hermetic connections are provided by soldering, respectively.

In addition, the protective wall 35 is also provided as a ceramic plate that is integrated with the second pad 33 by means of one of laminating, heat-cutting, and sintering. In combination with the aforementioned descriptions, that is, the first pad 31, the second pad 33 and the protective wall 35 are integrally fixed by means of one of laminating, heat-cutting, and sintering, such that the connector 30 is an integrated structure to be assembled with the tube shell 10.

Furthermore, reference is further made to FIG. 5, the upper surface 21 of the circuit board 20 is higher than the fourth area 303b; that is, in the top-down direction, the upper surface 21 is located above the fourth area 303b; moreover, the lower surface 23 of the circuit board 20 is lower than the second area 301b; that is, in the top-down direction, the lower surface 23 is located below the second area 301b. In this way, the circuit board 20 is limited to be not too low or too high relative to the second pad 33, which is conducive to shorten the length of the gold wire 53 used for high-frequency signal interconnection as much as possible to ensure high-frequency performance.

In this embodiment, the lower surface 23 of the circuit board 20 is flush with the fourth area 303b; in this way, the two are arranged at the same height in the top-down direction, thereby ensuring that the length of the gold wire 53 can be the shortest to maximally optimize the high-frequency performance.

Furthermore, referring to FIG. 6, the tube shell 10 also has a support pad 15 that extends rearward from the rear end wall 113, and the support pad 15 and the shell base 11 are integrally provided; the circuit board 20 is fixedly assembled with the support pad 15. In this way, through disposing the support pad 15, the fixed assembly between the circuit board 20 and the tube shell 10 is realized. On the one hand, this facilitates an adjustment of the positional relationship between the circuit board 20 and the connector 30 in the top-down and front-rear directions; on the other hand, during the assembly of the optical module 100, the gold wire 51 and the gold wire 53 can be disposed when the position between the circuit board 20 and the connector 30 is stable, so as to avoid the occurrence of abnormalities such as breakage of the gold wires.

In this embodiment, the support pad 15 is located below the circuit board 20, and the circuit board 20 is fixedly supported above the support pad 15, thereby facilitating a rapid heat dissipation of the circuit board 20 through the support pad 15. Correspondingly, the support pad 15 has a clearance groove 150 that is a top-down perforation, and the clearance groove 150 is used to expose a connection position of the connector 30 and the circuit board 20. Specifically, a projection range of the clearance groove 150 in the top-down direction at least covers gold wire solder joints on the high-frequency signal line 3G on the fourth area 303b and gold wire solder joints on the high-frequency signal line on the lower surface 23 of the circuit board 20, thereby facilitating a gold wire capillary to pass through the clearance groove 150 to dispose the gold wires 53.

Naturally, in a modified implementation, if the support pad 15 is changed to be located above the circuit board 20, correspondingly, the projection range of the clearance groove 150 in the top-down direction is change to cover at least the gold wire solder joints of the direct-current signal line 3D on the second area 301b and the gold wire solder joints on the direct-current signal line on the upper surface 21 of the circuit board 20, thereby facilitating the gold wire capillary to pass through the clearance slot 150 to dispose the gold wire 51.

In addition, referring to FIG. 5, the circuit board 20 and the support pad 15 are fixedly connected through a structural adhesive 60 therebetween. Naturally, the connection manner between the two is not limited thereto. Furthermore, the circuit board 20 is configured as a rigid circuit board, but it can naturally also be a flexible board in a modified embodiment.

Furthermore, referring to FIG. 1b, the chip carrier assembly 40 is thermally conductively connected to the tube shell 10; specifically, the carrier 43 of the chip carrier assembly 40 can be thermally conductively mounted to the bottom wall 115 through one or both of a heat sink and a cooler 70; that is: a heat sink can be provided between the carrier 43 and the bottom wall 115 for thermal conductive connection, or the cooler 70 can be provided for thermal conductive connection, or the cooler 70 and the heat sink can be provided at the same time for thermal conductive connection.

Furthermore, referring to FIG. 2b, the front end wall 111 of the tube shell 10 has an optical window 1110. Referring to FIG. 1b, the optical module 100 also includes an optical port assembly 91 mounted at the optical window 1110. The optical port assembly 91 can seal the optical window 1110; the optical module 100 can also include one or more of optical devices such as a collimating lens 93, a wavelength division multiplexing-demultiplexing element 95, an isolator 97, a coupling lens 99, a modulator, and a filter arranged in the tube shell 10 and disposed on an optical path between the optical port assembly 91 and the optical chip 41, and are specifically implemented in feasible manners known in the art that are not reiterated herein.

Furthermore, in the example as shown in the figures, the collimating lens 93 is mounted on the cooler 70, a thermal pad 92 is added between the carrier 43 of the chip carrier assembly 40 and the cooler 70, and the thermal pad 92 can facilitate the adjustment of the optical axis alignment between the optical chip 41 and the collimating lens 93.

The optical chip 40 in the chip carrier assembly 40 can be specifically configured as a laser chip. In this case, the optical module 100 can at least be used to implement a light emitting function; on the other hand, the optical chip 40 in the chip carrier assembly 40 can specifically be configured as a photodetector chip, such that the light module 100 can at least be used to implement the light emitting function. Naturally, the optical module 100 can also have both the light emitting function and the light receiving function, and correspondingly includes at least two optical chips 40, in which part of the optical chips 40 are configured as laser chips, and another part of the optical chips 40 are configured as photodetector chips.

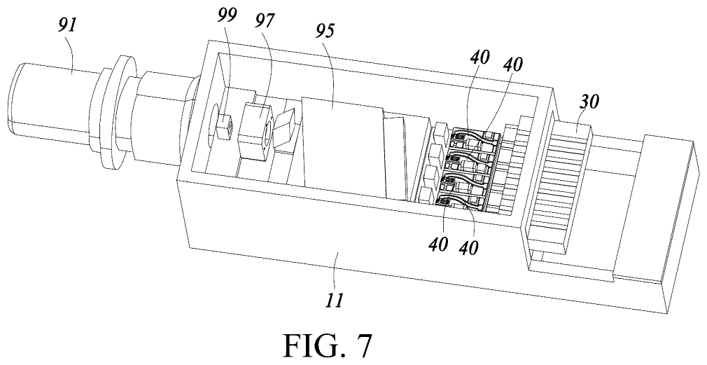

In addition, referring to FIG. 7, in this embodiment, the optical module 100 is configured as a multi-channel optical module that includes at least two chip carrier assemblies 40 arranged side by side in the left-right direction. The at least two chip carrier assemblies 40 are both electrically connected to the direct-current signal line 3D on the first area 301a and electrically connected to the high-frequency signal line 3G on the third area 303a; for each of the chip carrier assemblies 40, the specific structures thereof and the specific connection manners to the connector 30 are configured to be the same in this embodiment, are as described above, and naturally can also be configured to be different. In this way, by arranging at least two chip carrier assemblies 40 side by side in the left-right arrangement, the connector 30 and the chip carrier assemblies 40 arranged side by side simultaneously realize direct-current signal interconnections and high-frequency signal interconnections. Comparing with the existing multi-channel optical modules, the present embodiment has a more significant comprehensive effect of optimizing high-frequency performances while maintaining heat dissipation and processing reliability.

In the figures, a specific example of the optical module 100 is a four-channel optical module, and the corresponding four chip carrier assemblies 40 are arranged side by side in the left-right direction. Naturally, the number of channels of the optical module 100 is not limited thereto; for example, it can further be changed to eight channels; the corresponding eight chip carrier assemblies 40 can be arranged side by side in the left-right direction, or can be divided into upper and lower layers with four chip carrier assemblies 40 arranged side by side in each of the layers. In addition, in the modified implementation of the illustrated example, the optical module 100 can also be configured as a single-channel optical module that also has the advantages of optimizing high-frequency performance and having both heat dissipation and processing reliability.

Comparing with commonly used technologies, one embodiment of the present disclosure at least has the following advantageous effects: by providing the connector 30, specifically placing the surface 303 for the wiring of the high-frequency signal line 3G on the connector 30 and the surface 23 for the wiring of the high-frequency signal line on the circuit board 20 on the same side in the top-down direction (correspondingly, the surface 301 for the wiring of the direct-current signal line 3D on the connector 30 and the surface 23 for the wiring of the high-frequency signal line on the circuit board 20 are located on the same side in the top-down direction), and the third area 303a of the surface 303 inside the tube shell 10 and the fourth area 303b outside the tube shell 10 facing in opposite directions, the high-frequency signal connection between the connector 30 and the circuit board 20 can be realized with a very short length of the gold wire 53 and the number of impedance discontinuities in the high-speed link between the chip carrier assembly 40 and the circuit board 20 can be greatly reduced, which is conducive to the optimization of the high-frequency performance of the optical module 100.

It should be understood that, although the present specification is described in terms of implementations, each of the implementation may be not containing only one independent technical solution. Descriptions in the present specification are only provided for the sake of clarity, and persons skilled in the art should take the present specification as a whole, such that the technical solutions in the various embodiments can also be appropriately combined to form other embodiments that can be understood by those skilled in the art.

The series of detailed descriptions listed above are only specific descriptions of feasible implementations of the present application, and they are not intended to limit the protection scope of the present application. Any equivalent implementations or modifications that do not deviate from the technical spirit of the present application should be included in the protection scope of the present application.

1. An airtight optical module, comprising:
a box-shaped tube shell, a rear end wall of which is provided with a channel groove;
a connector being embedded in the channel groove and having an upper layer surface and a lower layer surface, wherein the upper layer surface is open upwards and includes a first area located in front of the rear end wall and a second area located behind the rear end wall, and the upper layer surface includes a direct-current signal line arranged thereon that extends from the first area to the second area; wherein the lower layer surface includes a third area located in front of the rear end wall and is open upwards and a fourth area located behind the rear end wall and is open downwards, and the lower layer surface includes a high-frequency signal line arranged thereon that extends from the third area to the fourth area;
a chip carrier assembly disposed in the tube shell and including an optical chip and a carrier that carries the optical chip, wherein the chip carrier assembly is electrically connected to the direct-current signal line of the first area and the high-frequency signal line of the third area; and
a circuit board, wherein a lower surface thereof has a high-frequency signal line arranged thereon and connected to the high-frequency signal line of the fourth area by means of a gold wire, and an upper surface of the circuit board has a direct-current signal line disposed thereon and connected to the direct-current signal line of the second area by means of a gold wire.

2. The airtight optical module according to claim 1, wherein the connector includes:
a first pad; and
a second pad, wherein a front end thereof is step-shaped and stacked on and fixed above the first pad, and a rear end thereof is suspended, the first area and the second area are defined on an upper surface of the second pad; wherein the fourth area is defined on a lower surface thereof, and a front part of the upper surface of the first pad is exposed by the second pad to form the third area.

3. The airtight optical module according to claim 2, wherein the carrier is provided in front of the first pad and electrically connected to the high-frequency signal line on the third area and the direct-current signal line on the first area, respectively, by mean of gold wires.

4. The airtight optical module according to claim 3, wherein the carrier is disposed separately from the connector.

5. The airtight optical module according to claim 2, wherein the connector is hermetically connected to the rear end wall to close the channel groove.

6. The airtight optical module according to claim 5, wherein the connector is connected to the rear end wall by means of soldering.

7. The airtight optical module according to claim 6, wherein the connector further includes a protective wall, the protective wall protrudes upwardly from the upper surface of the second pad to divide the first area and the second area, and an upper surface of the protective wall is hermetically connected to an upper groove wall of the channel groove.

8. The airtight optical module according to claim 7, wherein the first pad, the second pad, and the protective wall are provided as a ceramic plate and are integrally fixed by means of one of laminating, heat-cutting, and sintering.

9. The airtight optical module according to claim 1, wherein the upper surface of the circuit board is higher than the fourth area, and the lower surface of the circuit board is lower than the second area.

10. The airtight optical module according to claim 9, wherein the lower surface of the circuit board is flush with the fourth area.

11. The airtight optical module according to claim 1, wherein the tube shell has a support pad that extends rearward from the rear end wall, and the circuit board is fixedly assembled with the support pad.

12. The airtight optical module according to claim 11, wherein the support pad is located below the circuit board and has a clearance groove that is a top-down perforation; wherein a projection range of the clearance groove in a top-down direction covers gold wire solder joints on the high-frequency signal line in the fourth area and gold wire solder joints on the high-frequency signal line on the lower surface of the circuit board;
alternatively, the support pad is located above the circuit board and has a clearance groove that is a top-down perforation; wherein a projection range of the clearance groove in a top-down direction covers gold wire solder joints on the direct-current signal line of the second area and gold wire solder joints on the direct-current signal line on the upper surface of the circuit board.

13. The airtight optical module according to claim 1, wherein the tube shell includes a shell base and a cover plate, the shell base includes an upper opening and a bottom wall that is closed, and the cover plate seals the opening;
the carrier is thermally conductively mounted to the bottom wall through one or both of a heat sink and a cooler.

14. The airtight optical module according to claim 1, wherein a front end wall of the tube shell has an optical window; and the airtight optical module further comprising:
an optical port assembly mounted at the optical window; and
one or more of a collimating lens, a wavelength division multiplexing-demultiplexing element, an isolator, a coupling lens, a modulator, and a filter arranged in the tube shell and disposed between the optical port assembly and the optical chip.

15. The airtight optical module according to claim 1, wherein the optical chip is one of a laser chip and a photodetector chip.

16. An airtight optical module, comprising:
a tube shell defining an accommodating cavity, and a rear end wall of which is provided with a channel groove;
a connector being embedded in the channel groove, wherein the connector has a first pad with a high-frequency signal line arranged on an upper surface thereof, and a second pad with a direct-current signal line arranged on an upper surface thereof and a high-frequency signal line arranged on a lower surface thereof;
wherein a front end of the second pad is step-shaped and stacked on and fixed above the first pad, and extends into the accommodating cavity; wherein a rear end of the second pad is arranged behind the rear end wall and is suspended;
a chip carrier assembly disposed in the accommodating cavity and including an optical chip and a carrier that carries the optical chip, wherein the chip carrier assembly is electrically connected to the direct-current signal line on the upper surface of the second pad and the high-frequency signal line on the upper surface of the first pad; and
a circuit board disposed outside the accommodating cavity, wherein a lower surface thereof has a high-frequency signal line arranged thereon and connected to the high-frequency signal line of the lower surface of the second pad by means of a gold wire, and an upper surface thereof has a direct-current signal line arranged thereon and connected to the direct-current signal line of the upper surface of the second pad by means of a gold wire.

17. The airtight optical module according to claim 16, wherein the tube shell has a support pad that extends rearward from the rear end wall, and the circuit board is fixedly assembled with the support pad.

18. The airtight optical module according to claim 17, wherein the support pad has a clearance groove for exposing a connection position of the connector and the circuit board.

19. The airtight optical module according to claim 18, wherein the circuit board is a rigid circuit board.
